(19) United States
(12) Patent Application Publication
(10) Pub. No.: US 2026/0231613 A1
(43) Pub. Date: Aug. 6, 2026

(54) DISPLAY PANEL AND ELECTRONIC DEVICE INCLUDING THE SAME

(71) Applicant: Samsung Display Co., Ltd., Yongin-si (KR)

(72) Inventors: Wonwoo Choi, Yongin-si (KR); Dhohun Lee, Yongin-si (KR); Seongjun Lee, Yongin-si (KR); Kiyoung Kim, Yongin-si (KR); Minwoo Hyeon, Yongin-si (KR)

(21) Appl. No.: 19/428,497

(22) Filed: Dec. 22, 2025

(30) Foreign Application Priority Data
Feb. 3, 2025 (KR) 10-2025-0013287

(51) Int. Cl. H10K 59/121; H10K 59/35

(52) U.S. Cl. CPC H10K 59/1213; H10K 59/352

(57) ABSTRACT

Provided is a display panel including a substrate including a first display area, and a second display area including a circuit area and a non-circuit area, a first pixel circuit in the first display area, a first display element connected to the first pixel circuit, a second pixel circuit in the circuit area of the second display area, a second-1 display element in the circuit area, connected to the second pixel circuit, configured to emit light of a same color as the first display element, and having an emission area having a shape that is different from a shape of an emission area of the first display element, and a second-2 display element in the non-circuit area and connected to the second pixel circuit.

### CROSS-REFERENCE TO RELATED APPLICATION

The present application claims priority to, and the benefit of, Korean Patent Application No. 10-2025-0013287, filed on February 3, 2025, in the Korean Intellectual Property Office, the entire disclosure of which is incorporated herein by reference.

### BACKGROUND

### 1. Field

One or more embodiments relate to a display panel and an electronic device including the display panel.

### 2. Description of the Related Art

Recently, the use of display devices has become more diversified. In addition, as the display devices are becoming thinner and lighter, their range of use is further widening.

A display device includes a display panel, and the display panel includes a display element implementing a pixel and a pixel circuit configured to control an electrical signal applied to the display element. The pixel circuit includes a thin-film transistor (TFT), a capacitor, and a plurality of lines.

As the display devices are variously utilized, various methods may be used to design the shapes of the display devices. In addition, the number of functions that may be associated or linked to the display devices has also increased.

### SUMMARY

One or more embodiments include a display panel having an expanded display area so that an image may be displayed even in an area in which an electronic element, that is, a component, is located under the display panel, and an electronic device including the display panel. However, these aspects are examples, and the scope of the disclosure is not limited thereto.

Additional aspects will be set forth in part in the description which follows and, in part, will be apparent from the description, or may be learned by practice of the presented embodiments of the disclosure.

According to one or more embodiments, a display panel includes a substrate including a first display area, and a second display area including a circuit area and a non-circuit area, a first pixel circuit in the first display area, a first display element connected to the first pixel circuit, a second pixel circuit in the circuit area of the second display area, a second-1 display element in the circuit area, connected to the second pixel circuit, configured to emit light of a same color as the first display element, and having an emission area having a shape that is different from a shape of an emission area of the first display element, and a second-2 display element in the non-circuit area and connected to the second pixel circuit.

The circuit area and the non-circuit area may extend in a first direction in the second display area, wherein the circuit area and the non-circuit area are provided in plurality and alternately arranged in a second direction crossing the first direction.

A number of sub-pixels in the first display area per unit area may be substantially equal to a number of sub-pixels in the second display area per unit area.

A planar shape of the emission area of the first display element may be quadrangular, wherein a planar shape of the emission area of the second-1 display element and a planar shape of an emission area of the second-2 display element are circular.

A size of the emission area of the first display element may be greater than a size of the emission area of the second-1 display element.

The second-1 display element and the second-2 display element may be configured to emit light of a same color, wherein a size of the emission area of the second-1 display element is greater than a size of an emission area of the second-2 display element.

The second-1 display element and the second-2 display element may be configured to emit light of a same color, wherein a size of a pixel electrode of the second-1 display element is greater than a size of a pixel electrode of the second-2 display element.

A pixel electrode of the second-1 display element and a pixel electrode of the second-2 display element may be connected to each other by a connection line.

The connection line may include a transparent conductive oxide.

The connection line may be at a same layer as the pixel electrode of the second-1 display element.

The connection line may be at a different layer from the pixel electrode of the second-1 display element.

The display panel may further include an inorganic insulating layer above the substrate and defining an opening or groove corresponding to the non-circuit area.

The first pixel circuit may include a driving transistor including an oxide semiconductor material, and a switching transistor including a silicon semiconductor material.

According to one or more embodiments, an electronic device includes a processor, and a display panel configured to be driven by the processor, and including a substrate including a first display area and a second display area including a circuit area and a non-circuit area, a first pixel circuit in the first display area, a first display element connected to the first pixel circuit, a second pixel circuit in the circuit area, a second-1 display element in the circuit area, connected to the second pixel circuit, configured to emit light of a same color as the first display element, and having an emission area having a shape that is different from a shape of an emission area of the first display element, and a second-2 display element in the non-circuit area and connected to the second pixel circuit.

A number of sub-pixels in the first display area per unit area may be substantially equal to a number of sub-pixels in the second display area per unit area.

A planar shape of the emission area of the first display element may be quadrangular, wherein a planar shape of the emission area of the second-1 display element and a planar shape of an emission area of the second-2 display element are circular.

The first display element, the second-1 display element, and the second-2 display element may respectively include light-emitting diodes configured to emit light of a same color, wherein a size of the emission area of the first display element is greater than a size of the emission area of the second-1 display element, and wherein the size of the emission area of the second-1 display element is greater than a size of an emission area of the second-2 display element.

A pixel electrode of the second-1 display element and a pixel electrode of the second-2 display element may be connected to each other by a connection line.

The connection line may include a transparent conductive oxide.

The electronic device may further include a component below the display panel, and overlapping the second display area.

### BRIEF DESCRIPTION OF THE DRAWINGS

The above and other aspects of embodiments of the disclosure will be more apparent from the following description taken in conjunction with the accompanying drawings, in which:

FIG. 1 is a perspective view of an electronic device according to one or more embodiments;

FIG. 2 is an exploded perspective view of an electronic device according to one or more embodiments;

FIG. 3 is a schematic plan view of a display panel according to one or more embodiments;

FIG. 4 is a schematic cross-sectional view of an arrangement structure of pixels that may be located in a first display area, according to one or more embodiments;

FIG. 5 is an equivalent circuit diagram schematically illustrating a display element which may be included in a display panel and a pixel circuit electrically connected to the display element, according to one or more embodiments;

FIG. 6 is an equivalent circuit diagram schematically illustrating a display element which may be included in a display panel and a pixel circuit electrically connected to the display element, according to one or more embodiments;

FIG. 7 is a plan view showing a partial configuration of a display panel according to one or more embodiments;

FIG. 8 is a schematic layout diagram of an arrangement structure of pixels that may be located in a first display area, according to one or more embodiments;

FIG. 9 is a schematic layout diagram of an arrangement structure of pixels that may be located in a second display area, according to one or more embodiments;

FIG. 10 is a schematic layout diagram of an arrangement structure of pixels that may be located in a second display area, according to one or more embodiments;

FIG. 11 is a schematic cross-sectional view of a display panel according to one or more embodiments;

FIG. 12 is a schematic cross-sectional view of a display panel according to one or more embodiments;

FIG. 13 is a schematic cross-sectional view of a display panel according to one or more embodiments;

FIG. 14 is a block diagram of an electronic device according to one or more embodiments; and

FIG. 15 shows schematic diagrams of electronic devices according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

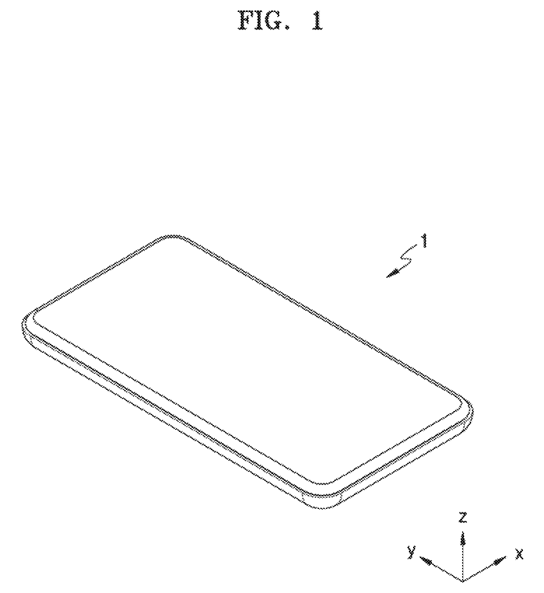

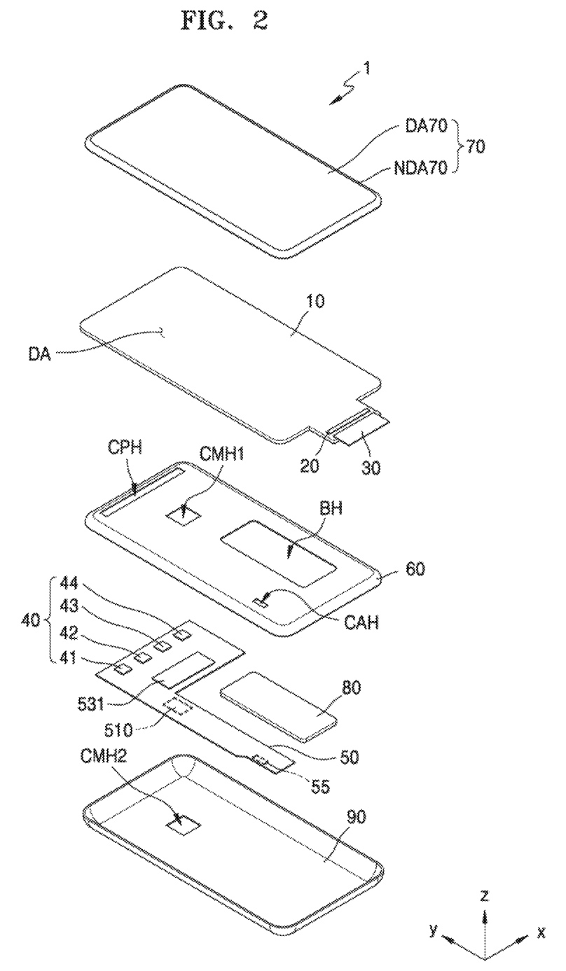

FIG. 1 is a perspective view of an electronic device 1 according to one or more embodiments, and FIG. 2 is an exploded perspective view of the electronic device 1 according to one or more embodiments.

Referring to FIGS. 1 and 2, the electronic device 1 according to one or more embodiments is shown as being used as a smartphone. The electronic device 1 according to one or more embodiments may include a cover window 70, a display panel 10, a data driver 20, a display circuit board 30, a component 40, a bracket 60, a main circuit board 50, a battery 80, and a lower cover 90.

In a plan view described in the specification, "left," "right," "above," and "below" may indicate directions when looking at the display panel 10 in a vertical direction of the display panel 10. For example, "left" may indicate a -x direction, "right" may indicate a +x direction, "above" may indicate a +y direction, and "below" may indicate a -y direction.

The electronic device 1 may have a rectangular shape in a plan view. For example, the electronic device 1 may have a rectangular planar shape having short sides in an x direction, and long sides in a y direction as shown in FIG. 1. A corner where a short side in the x direction and a long side in the y direction meet may be rounded to have a certain curvature or may be formed at a right angle. The planar shape of the electronic device 1 is not limited to a rectangular shape, and may be other polygonal, elliptical, or irregular shape.

The cover window 70 may be located on the display panel 10 to cover an upper surface of the display panel 10. Accordingly, the cover window 70 may function to protect the upper surface of the display panel 10.

The cover window 70 may include a transparent cover portion DA70 corresponding to the display panel 10 and a light-blocking portion NDA70 surrounding the transparent cover portion DA70. The light-blocking portion NDA70 may include an opaque material (e.g., a colored opaque material) that blocks light. The light-blocking portion NDA70 may include a pattern that may be shown to a user when an image is not displayed.

The display panel 10 provides an image and may be located below the cover window 70. The display panel 10 may overlap the transparent cover portion DA70 of the cover window 70.

The display panel 10 includes a display area DA. The display area DA is an area in which an image is displayed, and the display area DA may include an area (hereinafter referred to as a component area) through which light emitted by the component 40 located below the display panel 10 passes. The component 40 may include a sensor and camera using visible light, infrared light, or sound.

The display panel 10 displays (outputs) information processed by the electronic device 1. For example, the display panel 10 may display execution screen information of an application driven by the electronic device 1 or user interface (UI) or graphic user interface information according to the execution screen information.

The display panel 10 may be a light-emitting display panel including a light-emitting diode. The light-emitting diode may be an organic light-emitting diode including an organic emission layer. In some embodiments, the light-emitting diode may be an inorganic light-emitting diode including an inorganic material. The inorganic light-emitting diode may include a PN junction diode including materials based on inorganic semiconductors. When a voltage is applied to the PN junction diode in a forward direction, holes and electrons may be injected, and energy generated by recombination of the holes and electrons may be converted into light energy to emit a certain color of light. The inorganic light-emitting diode described above may have a width of several micrometers to several hundreds of micrometers, and in some embodiments, the inorganic light-emitting diode may be referred to as a micro light-emitting diode (LED).

The display panel 10 may be a rigid display panel that is rigid, and thus is not easily bent, or may be a flexible display panel that is flexible and thus may be suitably bent, folded, or rolled. For example, the display panel 10 may be a foldable display panel that may be folded and unfolded, a curved display panel of which a display surface is bent, a bent display panel having an area other than a display surface bent, a rollable display panel that may be rolled and unrolled, and a stretchable display panel that may be stretched.

The display panel 10 may be a transparent display panel that is implemented to be transparent, so that an object or a background located on a lower surface of the display panel 10 may be viewed from the upper surface of the display panel 10. Alternatively, the display panel 10 may be a reflective display panel which may reflect an object of a background on the upper surface of the display panel 10.

The data driver 20 may be located on the display panel 10 in a form of an integrated circuit (IC). In one or more other embodiments, the data driver 20 may be located on the display circuit board 30.

The display circuit board 30 may be attached to one side of the display panel 10. The display circuit board 30 may be a flexible printed circuit board (FPCB) that may be bent or a composite printed circuit board including both of a rigid printed circuit board (RPCB) that is hard and is not easily bendable and an FPCB.

In one or more embodiments, a touch sensor driver may be located on the display circuit board 30. The touch sensor driver may be formed as an IC. The touch sensor driver may be attached on the display circuit board 30. The touch sensor driver may be electrically connected to touch electrodes of a touch screen layer of the display panel 10 through the display circuit board 30.

The touch screen layer of the display panel 10 may sense a user's touch input by using at least one of various touch methods, such as a resistive film method, a capacitive method, or the like. For example, when the touch screen layer of the display panel 10 senses a user's touch input by using a capacitive method, the touch sensor driver may determine whether the user touches by applying driving signals to driving electrodes among the touch electrodes and sensing voltages charged in mutual capacitances (hereinafter, referred to as "mutual capacities") between the driving electrodes and sensing electrodes through the sensing electrodes among the touch electrodes. The user's touch may include a contact touch and a proximity touch. The contact touch refers to a touch in which an object, such as a user's finger, a pen, or the like, directly contacts the cover window 70 located on the touch screen layer. The proximity touch refers to a touch in which an object, such as a user's finger, a pen, or the like, is positioned proximately on the cover window 70, such as hovering. The touch sensor driver may transmit sensor data to a main processor 510 according to sensed voltages, and the main processor 510 may calculate touch coordinates in which a touch input has occurred by analyzing the sensor data.

A controller configured to supply driving voltages for driving pixels of the display panel 10, a scan driver, and the data driver 20 may be located on the display circuit board 30.

The bracket 60 configured to support the display panel 10 may be located below the display panel 10. The bracket 60 may include plastic, metal, or both plastic and metal. A first camera hole CMH1 into which a camera device 531 is inserted, a battery hole BH in which the battery 80 is located, and a cable hole CAH through which a cable connected to the display circuit board 30 passes, may be formed in the bracket 60. A component hole CPH overlapping the display panel 10 may be provided in the bracket 60. The component hole CPH may overlap components 40 of the main circuit board 50 in a third direction (z direction). In one or more embodiments, the display area DA of the display panel 10 may overlap the components 40 of the main circuit board 50 in the third direction (z direction). In one or more other embodiments, the component hole CPH may not be formed in the bracket 60.

In one or more embodiments, the components 40 may include first to fourth components 41, 42, 43, and 44, which overlap the display panel 10. The first to fourth components 41, 42, 43, and 44 may respectively be provided as a proximity sensor, an illuminance sensor, an iris sensor , a facial recognition sensor, and a camera (or an image sensor). The proximity sensor using infrared light may detect an object located close to an upper surface of the electronic device 1, and the illuminance sensor may sense the brightness of light incident to the upper surface of the electronic device 1. In addition, the iris sensor may capture an image of an iris of a person located on the upper surface of the electronic device 1, and the camera may capture an image of an object located on the upper surface of the electronic device 1. The component 40 is not limited to the proximity sensor, the illuminance sensor, the iris sensor, the facial recognition sensor, and the camera, and may include various other sensors.

The main circuit board 50 and the battery 80 may be located below the bracket 60. The main circuit board 50 may be a printed circuit board or a FPCB.

The main circuit board 50 may include the main processor 510, the camera device 531, a main connector 55, and the components 40. The main processor 510 may be formed as an IC. The camera device 531 may be located on both of upper and lower surfaces of the main circuit board 50, and each of the main processor 510 and the main connector 55 may be located on any one of the upper surface and the lower surface of the main circuit board 50.

The main processor 510 may control all functions of the electronic device 1. For example, the main processor 510 may output digital video data to the data driver 20 through the display circuit board 30 so that the display panel 10 displays an image. The main processor 510 may receive sensing data from the touch sensor driver. The main processor 510 may determine whether a user has touched according to the sensing data and execute an operation corresponding to the user's direct touch or proximity touch. The main processor 510 may be an application processor, a central processing unit, or a system chip, which includes an IC.

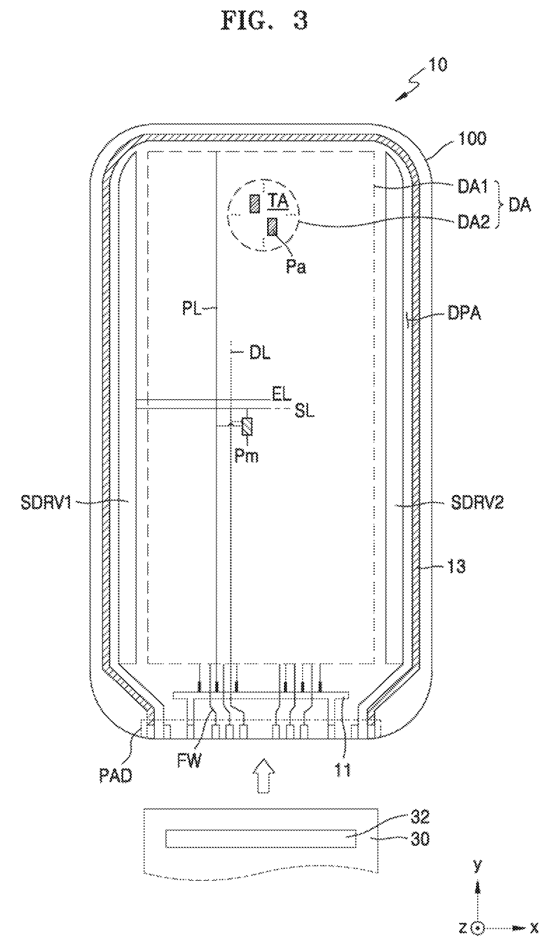

The camera device 531 processes an image frame, such as a still image, a video, or the like, obtained by an image sensor in a camera mode and outputs the processed image frame to the main processor 510. The camera device 531 may include at least one of a camera sensor (for example, a charge-coupled device (CCD), a complementary metal-oxide-semiconductor (CMOS), or the like), a photo sensor (or an image sensor), or a laser sensor. The camera device 531 may be connected to an image sensor among the components 40 overlapping a second display area DA2 (refer to FIG. 3) and process an image input with the image sensor.

A cable passing through the cable hole CAH of the bracket 60 may be connected to the main connector 55, and accordingly, the main circuit board 50 may be electrically connected to the display circuit board 30.

The battery 80 may be located not to overlap (e.g., to be separated from, in plan view) the main circuit board 50 in the third direction (z direction). The battery 80 may overlap the battery hole BH of the bracket 60.

The lower cover 90 may form the exterior of the electronic device 1 and may have an opening in a front surface thereof to expose a portion of the display panel 10. A surface of the lower cover 90, which corresponds to the display panel 10, has an open shape, and the lower cover 90 may be assembled with the display panel 10. The lower cover 90 may be positioned on an opposite side of the cover window 70 with the display panel 10 therebetween. The lower cover 90 may be located below the main circuit board 50 and the battery 80. The lower cover 90 may be fastened and fixed to the bracket 60. The lower cover 90 may form the exterior of a lower surface of the electronic device 1. The lower cover 90 may include plastic, metal, or both plastic and metal.

A second camera hole CMH2 exposing a lower surface of the camera device 531 may be formed in the lower cover 90. A position of the camera device 531 and positions of the first and second camera holes CMH1 and CMH2 corresponding to the camera device 531 are not limited to the embodiments corresponding to FIGS. 1 and 2, and may be changed in various ways.

FIG. 3 is a schematic plan view of the display panel 10 according to one or more embodiments.

Referring to FIG. 3, various types of components forming the display panel 10 are located on a substrate 100. The substrate 100 includes the display area DA and a peripheral area DPA surrounding the display area DA. The display area DA may include a first display area DA1 in which a main image is displayed, and a second display area DA2 having a transmission area TA and in which an auxiliary image is displayed. The auxiliary image may also form a single overall image together with the main image, or the auxiliary image may also be an image independent from the main image.

A plurality of main sub-pixels Pm are located in the first display area DA1. Each of the plurality of main sub-pixels Pm may be implemented as a display element, such as an organic light-emitting diode (OLED). Each main sub-pixel Pm may emit, for example, red, green, blue, or white light. The first display area DA1 may be covered with an encapsulation member to be protected from external air or moisture.

The second display area DA2 may be an area overlapping a component, such as a camera or a sensor, located below the display panel 10. The second display area DA2 may be located inside the display area DA, and may be surrounded by the first display area DA1. Alternatively, the second display area DA2 may be located on one side of the first display area DA1. A plurality of auxiliary sub-pixels Pa are located in the second display area DA2. Each of the plurality of auxiliary sub-pixels Pa may be implemented by a display element, such as an organic light-emitting diode (OLED). Each auxiliary sub-pixel Pa may emit, for example, red, green, blue, or white light. The second display area DA2 may be covered with an encapsulation member to be protected from external air or moisture.

The second display area DA2 may have the transmission area TA through which light passes. The transmission area TA may be an area in the second display area DA2, in which elements for blocking light are not located, or are omitted. The transmission area TA may be an area in which a transistor, a capacitor, a line, or the like are not located. The transmission area TA may be an area in the second display area DA2, in which the auxiliary sub-pixels Pa are not located. The transmission area TA may be surrounded by the plurality of auxiliary sub-pixels Pa or may be located alternately with the plurality of auxiliary sub-pixels Pa.

Each of pixel circuits driving the main sub-pixels Pm and the auxiliary sub-pixels Pa may be electrically connected to outer circuits located in the peripheral area DPA. A first scan-driving circuit SDRV1, a second scan-driving circuit SDRV2, a terminal portion PAD, a driving voltage supply line 11, and a common voltage supply line 13 may be located in the peripheral area DPA.

The first scan-driving circuit SDRV1 may apply a scan signal to each of the pixel circuits driving the main sub-pixels Pm and the auxiliary sub-pixels Pa through a second scan line SL. The first scan-driving circuit SDRV1 may apply an emission control signal to each pixel circuit through an emission control line EL. The second scan-driving circuit SDRV2 may be positioned on the opposite side to the first scan-driving circuit SDRV1 with the first display area DA1 as a center, and may be substantially parallel to the first scan-driving circuit SDRV1. Some pixel circuits of the main sub-pixels Pm of the first display area DA1 may be electrically connected to the first scan-driving circuit SDRV1, and the remaining pixel circuits may be electrically connected to the second scan-driving circuit SDRV2. Some pixel circuits of the auxiliary sub-pixels Pa of the second display area DA2 may be electrically connected to the first scan-driving circuit SDRV1, and the remaining pixel circuits may be electrically connected to the second scan-driving circuit SDRV2. The second scan-driving circuit SDRV2 may be omitted.

The terminal portion PAD may be located on one side of the substrate 100. The terminal portion PAD may be exposed without being covered by an insulating layer to be connected to a display circuit board 30. A display driver 32 may be located in the display circuit board 30.

The display driver 32 may generate a control signal to be transmitted to the first scan-driving circuit SDRV1 and the second scan-driving circuit SDRV2. The display driver 32 may generate a data signal, and the generated data signal may be transmitted to the pixel circuits of the main sub-pixels Pm and the auxiliary sub-pixels Pa through a fan-out line FW and a data line DL connected to the fan-out line FW.

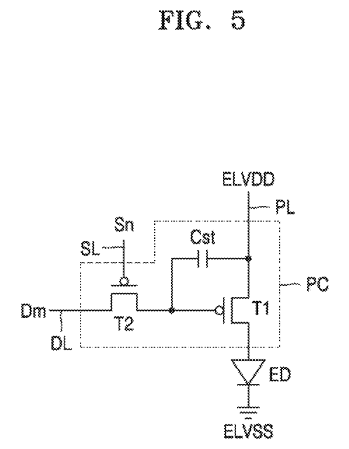

The display driver 32 may supply a driving voltage ELVDD (see FIG. 5) to the driving voltage supply line 11, and may supply a common voltage ELVSS (see FIG. 5) to the common voltage supply line 13. The driving voltage ELVDD may be applied to the pixel circuits of the main sub-pixels Pm and the auxiliary sub-pixels Pa through a driving voltage line PL connected to the driving voltage supply line 11, and the common voltage ELVSS may be applied to an opposite electrode of a display element through the common voltage supply line 13.

The driving voltage supply line 11 may be provided extending in an x direction from a lower side of the first display area DA1. The common voltage supply line 13 may have a loop shape with one side open to partially surround the first display area DA1.

FIG. 3 illustrates a case where one second display area DA2 is provided, but a plurality of second display areas DA2 may be provided. In this case, the plurality of second display areas DA2 may be spaced apart from each other, a first camera may correspond to one second display area DA2, and a second camera may correspond to another second display area DA2. Alternatively, a camera may correspond to one second display area DA2, and an infrared sensor may correspond to another second display area DA2. The shapes and sizes of the plurality of second display areas DA2 may be provided differently.

The second display area DA2 may be provided in a polygonal shape. For example, the second display area DA2 may be provided in an octagonal shape. The second display area DA2 may be provided in various polygonal shapes, such as a quadrangular shape, a hexagonal shape, or the like.

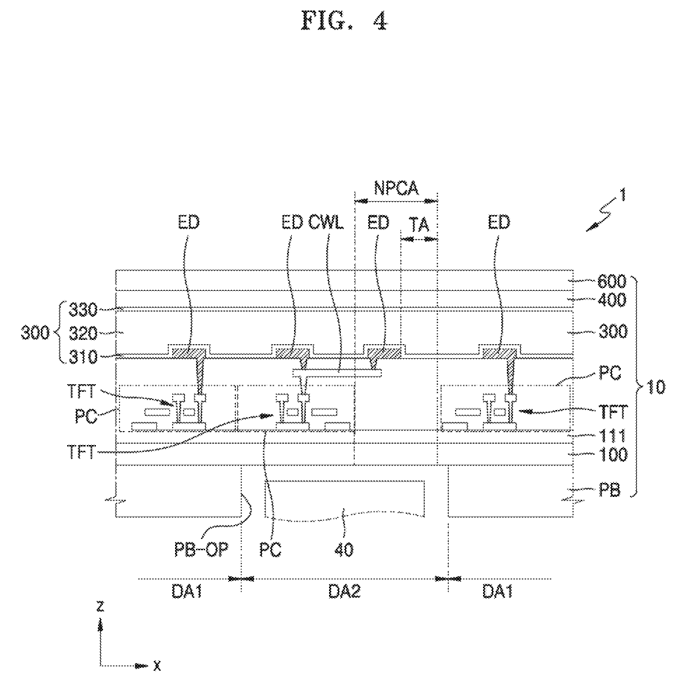

FIG. 4 is a cross-sectional view of a portion of the electronic device 1 according to one or more embodiments.

Referring to FIG. 4, the electronic device 1 may include the display panel 10 and the component 40 overlapping the display panel 10 and located on a lower surface of the display panel 10. The component 40 may correspond to the second display area DA2.

The display panel 10 may include a substrate 100, a pixel circuit PC including a thin-film transistor TFT located above the substrate 100, a display element (e.g., a light-emitting diode ED) electrically connected to the pixel circuit PC, a thin-film encapsulation layer 300 covering the display element, an input-sensing layer 400, and an optical functional layer 600.

The substrate 100 may include glass or a polymer resin. The substrate 100 including the polymer resin may be flexible, foldable, rollable, or bendable. The substrate 100 may have a multi-layered structure including a layer including the above-described polymer resin, and an inorganic layer, in one or more embodiments.

A lower protective film PB may be located on a lower surface of the substrate 100 (as used herein, “located on” may mean “above”). The lower protective film PB may be attached to the lower surface of the substrate 100. An adhesive layer may be between the lower protective film PB and the substrate 100. Alternatively, the lower protective film PB may be directly formed on a rear surface of the substrate 100, and in this case, an adhesive layer may not be between the lower protective film PB and the substrate 100.

The lower protective film PB may serve to support and protect the substrate 100. The lower protective film PB may have, or define, an opening PB-OP corresponding to the second display area DA2. The lower protective film PB may include an organic insulating material, such as polyethylene terephthalate (PET) or polyimide (PI).

The thin-film transistor TFT and the light-emitting diode ED as a display element electrically connected to the thin-film transistor TFT may be located above an upper surface of the substrate 100.

The light-emitting diode ED may be an organic light-emitting diode including an organic material. The organic light-emitting diode may emit red, green, or blue light. The light-emitting diode ED may be an inorganic light-emitting diode including an inorganic material. The inorganic light-emitting diode may include a PN junction diode including materials based on inorganic semiconductors. When a voltage is applied to the PN junction diode in a forward direction, holes and electrons may be injected, and energy generated by recombination of the holes and electrons may be converted into light energy to emit a certain color of light. The above-described inorganic light-emitting diode may have a width of several to several hundred micrometers, or several to several hundred nanometers. In some embodiments, the light-emitting diode ED may include a quantum dot light-emitting diode. An emission layer of the light-emitting diode ED may include an organic material, an inorganic material, a quantum dot, an organic material and a quantum dot, or an inorganic material and a quantum dot.

The light-emitting diode ED may be electrically connected to the thin-film transistor TFT located below the light-emitting diode ED. In this regard, FIG. 4 illustrates that a buffer layer 111 is located on the substrate 100, and the thin-film transistor TFT is located on the buffer layer 111. The thin-film transistor TFT and the light-emitting diode ED electrically connected to the thin-film transistor TFT may be located in each of the first display area DA1 and the second display area DA2.

A non-circuit area NPCA may be located in the second display area DA2. The non-circuit area NPCA is an area in which a member configuring a pixel circuit, such as a thin-film transistor or a capacitor, is not located (e.g., is omitted), and may be an area with high light transmittance.

A pixel circuit is not located in the non-circuit area NPCA, but the light-emitting diode ED, which is a display element, may be located in the non-circuit area NPCA. A light-emitting diode located in the non-circuit area NPCA may be connected to the pixel circuit PC through a connection line CWL.

The non-circuit area NPCA may include the transmission area TA. The transmission area TA is an area in which the pixel circuit PC or the light-emitting diode ED is not located, and the transmission area TA is an area through which light emitted from the component 40 and/or light toward the component 40 may pass. In the display panel 10, the transmittance of the transmission area TA may be about 30% or more, about 40% or more, about 50% or more, about 60% or more, about 70% or more, about 75% or more, about 80% or more, about 85% or more, or about 90% or more.

The component 40 may include a sensor, such as a proximity sensor, an illuminance sensor, an iris sensor, and a facial recognition sensor, and a camera (or an image sensor). The component 40 may emit and/or receive light in the infrared, ultraviolet, and visible light bands.

The thin-film encapsulation layer 300 may cover light-emitting diodes ED. The thin-film encapsulation layer 300 may include at least one inorganic encapsulation layer and at least one organic encapsulation layer. In one or more embodiments, the thin-film encapsulation layer 300 may include first and second inorganic encapsulation layers 310 and 330 and an organic encapsulation layer 320 therebetween.

The input-sensing layer 400 may be formed on the thin-film encapsulation layer 300. The input-sensing layer 400 may obtain coordinate information according to an external input, for example, a touch event of an object, such as a finger or a stylus pen. The input-sensing layer 400 may include a touch electrode and trace lines connected to the touch electrode. The input-sensing layer 400 may sense an external input in a mutual-cap method or a self-cap method.

The optical functional layer 600 may include an anti-reflection layer. The anti-reflection layer may reduce reflectance of light (external light) incident from the outside toward the electronic device 1. In some embodiments, the optical functional layer 600 may be a polarizing film. In some embodiments, the optical functional layer 600 may include a filter plate including a black matrix and color filters.

FIG. 5 is an equivalent circuit diagram schematically illustrating a display element which may be included in a display panel and a pixel circuit electrically connected to the display element, according to one or more embodiments. The display element may be the light-emitting diode ED.

Referring to FIG. 5, the pixel circuit PC may include a first transistor T1, a second transistor T2, and a storage capacitor Cst. The first transistor T1 may be a driving transistor, and the second transistor T2 may be a data write transistor.

The second transistor T2 may be connected to a scan line SL and a data line DL, and may be configured to deliver, to the first transistor T1, a data voltage (or a data signal Dm) input from the data line DL based on a switching voltage (or a switching signal Sn) input from the scan line SL. The storage capacitor Cst may be connected to the second transistor T2 and a driving voltage line PL and store a voltage corresponding to the difference between a voltage received from the second transistor T2 and a driving voltage ELVDD supplied to the driving voltage line PL.

The first transistor T1 may be connected to the driving voltage line PL and the storage capacitor Cst, and may control a driving current flowing from the driving voltage line PL to the light-emitting diode ED, in accordance to a voltage value stored in the storage capacitor Cst. The light-emitting diode ED may emit light having a certain brightness according to the driving current. An opposite electrode (e.g., a cathode) of the light-emitting diode ED may receive the common voltage ELVSS.

FIG. 5 illustrates that the pixel circuit PC includes two thin-film transistors and one storage capacitor, but the disclosure is not limited thereto. The number of thin-film transistors and the number of storage capacitors may be variously changed according to the design of the pixel circuit PC. For example, the pixel circuit PC may include three, four, five, or more thin-film transistors. In addition, the pixel circuit PC may include a plurality of capacitors.

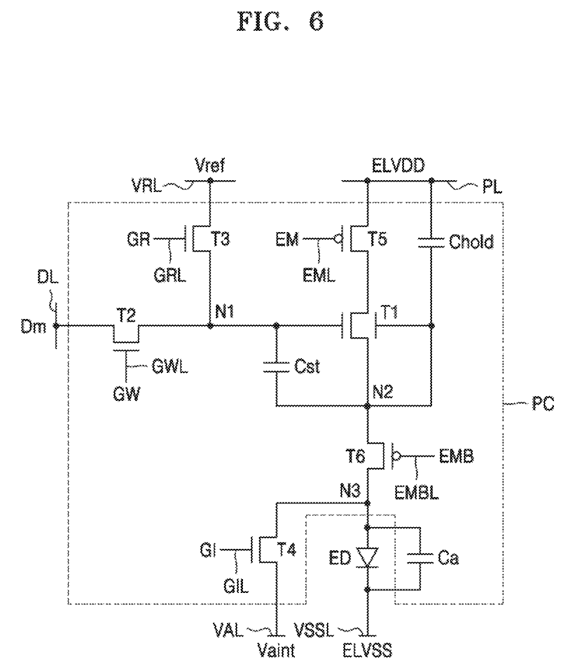

FIG. 6 is an equivalent circuit diagram schematically illustrating a display element which may be included in a display panel and a pixel circuit electrically connected to the display element, according to one or more embodiments.

The pixel circuit PC may be electrically connected to a first gate line GWL configured to transmit a first gate signal GW, a second gate line GRL configured to transmit a second gate signal GR, a third gate line EML configured to transmit a third gate signal EM, a fourth gate line GIL configured to transmit a fourth gate signal GI, a fifth gate line EMBL configured to transmit a fifth gate signal EMB, and the data line DL configured to transmit the data signal Dm. Because light emission of the light-emitting diode ED is controlled by the third gate signal EM and the fifth gate signal EMB, the third gate signal EM and the fifth gate signal EMB may be referred to emission control signals, and the third gate line EML and the fifth gate line EMBL may be referred to as emission control lines. The pixel circuit PC may be electrically connected to the driving voltage line PL configured to transmit the driving voltage ELVDD, a reference voltage line VRL configured to transmit a reference voltage Vref, and an initialization voltage line VAL configured to transmit an initialization voltage Vaint.

In one or more embodiments, some of a plurality of transistors included in the pixel circuit PC may be N-type transistors, and some others thereof may be P-type transistors. First to fourth transistors T1, T2, T3, and T4 may be N-type transistors, and fifth and sixth transistors T5 and T6 may be P-type transistors. Semiconductor layers of the first to fourth transistors T1, T2, T3, and T4 may include different materials from semiconductor layers of the fifth and sixth transistors T5 and T6. In some embodiments, the first to fourth transistors T1, T2, T3, and T4 may each include an oxide semiconductor material, and the fifth and sixth transistors T5 and T6 may each include amorphous silicon, polysilicon, or an organic material semiconductor.

The pixel circuit PC may include first to sixth transistors T1, T2, T3, T4, T5, and T6, a storage capacitor Cst, a holding capacitor Chold, and an auxiliary capacitor Ca. The first transistor T1 may be a driving transistor that outputs a driving current corresponding to the data signal Dm, and the second to sixth transistors T2, T3, T4, T5, and T6 may be switching transistors configured to transmit signals. The first transistor T1 may be referred to as a driving transistor, the second transistor T2 may be referred to as a data write transistor, the third transistor T3 may be referred to as a compensation transistor, the fourth transistor T4 may be referred to as an initialization transistor, the fifth transistor T5 may be referred to as an operation control transistor, and the sixth transistor T6 may be referred to as an emission control transistor.

A first terminal (or a first electrode) and a second terminal (or a second electrode) of each of the first to sixth transistors T1, T2, T3, T4, T5, and T6 may be a source (or a source electrode) or a drain (or a drain electrode) according to voltages of the first terminal and the second terminal, respectively. For example, according to the voltages of the first terminal and the second terminal, the first terminal may be a drain and the second terminal may be a source, or the first terminal may be a source and the second terminal may be a drain. Hereinafter, a node connected to a first-1 gate electrode of the first transistor T1 may be defined as a first node N1, and a node connected to the second terminal of the first transistor T1 may be defined as a second node N2.

The first transistor T1 may be connected to the driving voltage line PL and the light-emitting diode ED. The first transistor T1 may be connected between the fifth transistor T5 and the sixth transistor T6. The first transistor T1 may include a first gate (or a first gate electrode), the first terminal, and the second terminal connected to the second node N2. The first transistor T1 may include the first-1 gate connected to the first node N1. The first transistor T1 may further include a first-2 gate connected to the second terminal thereof. The first-1 gate and the first-2 gate may be located on different layers to face each other. For example, the first-1 gate and the first-2 gate of the first transistor T1 may face each other with a semiconductor layer therebetween. Herein, the first gate (or the first gate electrode) of the first transistor T1 may represent the first-1 gate (or the first-1 gate electrode) involved in turning-on and turning-off of the first transistor T1.

A gate (or the first-1 gate) of the first transistor T1 may be connected to the second terminal of the second transistor T2, the first terminal of the third transistor T3, and the storage capacitor Cst. The first-2 gate of the first transistor T1 may be connected to the first terminal of the sixth transistor T6, the storage capacitor Cst, and the holding capacitor Chold. The first terminal of the first transistor T1 may be connected to the driving voltage line PL via the fifth transistor T5, and the second terminal thereof may be connected to a pixel electrode of the light-emitting diode ED via the sixth transistor T6. The first terminal of the first transistor T1 may be connected to the second terminal of the fifth transistor T5. The second terminal of the first transistor T1 may be connected to the first terminal of the sixth transistor T6, the storage capacitor Cst, and the holding capacitor Chold. The first transistor T1 may receive the data signal Dm in response to a switching operation of the second transistor T2 and control a current amount of a driving current flowing to the light-emitting diode ED.

The second transistor T2 may be connected to the data line DL and a gate (e.g., first-1 gate) of the first transistor T1. The second transistor T2 may include a gate connected to the first gate line GWL, a first terminal connected to the data line DL, and a second terminal connected to the first node N1. The second terminal of the second transistor T2 may be connected to the gate of the first transistor T1, the first terminal of the third transistor T3, and the storage capacitor Cst. The second transistor T2 may be turned on by the first gate signal GW transmitted through the first gate line GWL to electrically connect the data line DL to the first node N1, and may be configured to transmit the data signal Dm transmitted through the data line DL to the first node N1.

The third transistor T3 may be connected to the gate of the first transistor T1 and the reference voltage line VRL. The third transistor T3 may include the a gate connected to the second gate line GRL, a first terminal connected to the first node N1, and a second terminal connected to the reference voltage line VRL. The first terminal of the third transistor T3 may be connected to the gate of the first transistor T1, the second terminal of the second transistor T2, and the storage capacitor Cst. The third transistor T3 may be turned on by the second gate signal GR transmitted through the second gate line GRL to be configured to transmit the reference voltage Vref transmitted through the reference voltage line VRL to the first node N1.

The fourth transistor T4 may be connected to the sixth transistor T6 and the initialization voltage line VAL. The fourth transistor T4 may be connected between the light-emitting diode ED and the initialization voltage line VAL. The fourth transistor T4 may include a gate connected to the fourth gate line GIL, a first terminal connected to a third node N3, and a second terminal connected to the initialization voltage line VAL. The first terminal of the fourth transistor T4 may be connected to the second terminal of the sixth transistor T6 and a pixel electrode of the light-emitting diode ED. The fourth transistor T4 may be turned on by the fourth gate signal GI transmitted through the fourth gate line GIL to be configured to transmit the initialization voltage Vaint transmitted through the initialization voltage line VAL to the third node N3, and may initialize the pixel electrode (e.g., an anode) of the light-emitting diode ED.

The fifth transistor T5 may be connected to the driving voltage line PL and the first transistor T1. The fifth transistor T5 may include a gate connected to the third gate line EML, a first terminal connected to the driving voltage line PL, and a second terminal connected to the first terminal of the first transistor T1. The fifth transistor T5 may be turned on or off in response to the third gate signal EM transmitted through the third gate line EML.

The sixth transistor T6 may be connected to the first transistor T1 and the light-emitting diode ED. The sixth transistor T6 may be connected between the second node N2 and the third node N3. The sixth transistor T6 may include a gate connected to the fifth gate line EMBL, a first terminal connected to the second node N2, and a second terminal connected to the third node N3. The first terminal of the sixth transistor T6 may be connected to the second terminal of the first transistor T1, the storage capacitor Cst, and the holding capacitor Chold. The second terminal of the sixth transistor T6 may be connected to the first terminal of the fourth transistor T4 and the pixel electrode of the light-emitting diode ED. The sixth transistor T6 may be turned on or off in response to the fifth gate signal EMB transmitted through the fifth gate line EMBL.

The storage capacitor Cst may be connected between the gate of the first transistor T1 and the second terminal of the first transistor T1. A first electrode of the storage capacitor Cst may be connected to the first node N1, and a second electrode thereof may be connected to the second node N2. The first electrode of the storage capacitor Cst may be connected to the gate of the first transistor T1, the second terminal of the second transistor T2, and the first terminal of the third transistor T3. The second electrode of the storage capacitor Cst may be connected to the second terminal and the first-2 gate of the first transistor T1, a second electrode of the holding capacitor Chold, and the first terminal of the sixth transistor T6. The storage capacitor Cst is a storage capacitor, which may store a threshold voltage of the first transistor T1 and a voltage corresponding to the data signal Dm.

When the third transistor T3 and the fifth transistor T5 are turned on, the first transistor T1 may be turned on. When a voltage of the second terminal of the first transistor T1 drops to the difference (Vref-Vth1) between the reference voltage Vref and a threshold voltage Vth1 of the first transistor T1, the first transistor T1 may be turned off, and a voltage corresponding to the threshold voltage Vth1 of the first transistor T1 may be stored in the storage capacitor Cst, so that the threshold voltage Vth1 of the first transistor T1 may be compensated.

The holding capacitor Chold may be connected between the driving voltage line PL and the second node N2. A first electrode of the holding capacitor Chold may be connected to the driving voltage line PL. The second electrode of the holding capacitor Chold may be connected to the second terminal and the first-2 gate of the first transistor T1, the second electrode of the storage capacitor Cst, and the first terminal of the sixth transistor T6.

The capacitance of each of the storage capacitor Cst and the holding capacitor Chold may vary depending on the color of light emitted by the light-emitting diode ED.

The auxiliary capacitor Ca may be electrically connected to the sixth transistor T6, a maintenance voltage line VSSL, and the pixel electrode of the light-emitting diode ED. The auxiliary capacitor Ca may store and maintain a voltage corresponding to a voltage difference between the pixel electrode of the light-emitting diode ED and the maintenance voltage line VSSL to reduce or prevent the likelihood or extent of a problem in which black brightness increases when the sixth transistor T6 is turned off.

The light-emitting diode ED may be connected to the first transistor T1 via the sixth transistor T6. The light-emitting diode ED may include the pixel electrode (anode) connected to the third node N3 and the opposite electrode (cathode) facing the pixel electrode, and the opposite electrode may receive the common voltage ELVSS. In one or more embodiments, the opposite electrode (cathode) may extend to a display area and may be electrically connected to the maintenance voltage line VSSL providing the common voltage ELVSS. A driving current output by the first transistor T1 may flow through the light-emitting diode ED by the fifth transistor T5 and the sixth transistor T6, which are turned on, and the light-emitting diode ED may emit light having a brightness corresponding to the magnitude of the driving current.

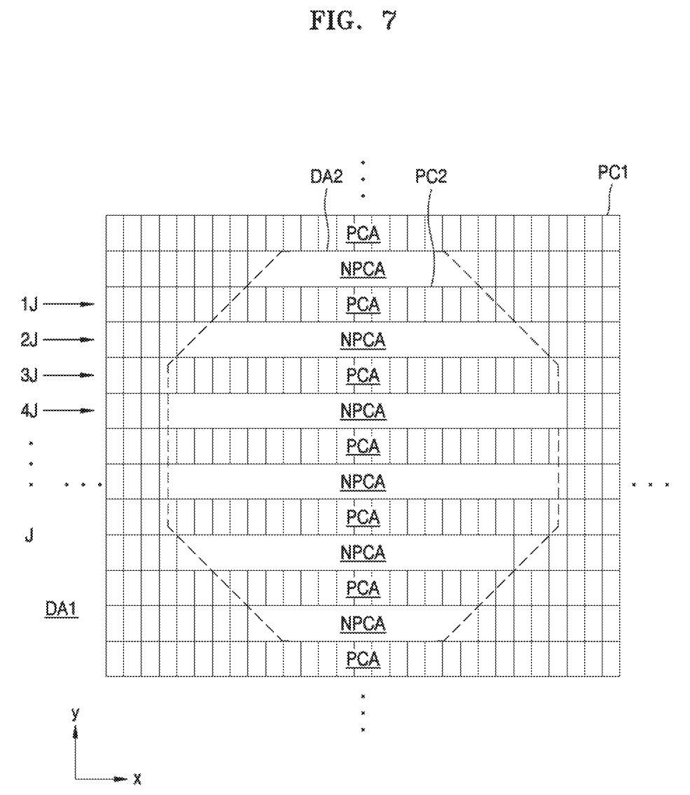

FIG. 7 is a plan view showing a partial configuration of a display panel according to one or more embodiments. In detail, a second display area and pixel circuits located in a first display area around the second display area are shown.

Referring to FIG. 7, a plurality of first pixel circuits PC1 may be located in a matrix form in an x direction and a y direction in the first display area DA1. The second display area DA2 may include a circuit area PCA in which a plurality of second pixel circuits PC2 are located, and the non-circuit area NPCA in which pixel circuits are not located/are omitted.

The second display area DA2 may be surrounded by the first display area DA1. The second display area DA2 may be provided in various shapes, such as a polygonal shape, a circular shape, or an elliptical shape. FIG. 7 shows a case where the second display area DA2 is provided in an octagonal shape.

The second display area DA2 may include the circuit area PCA and the non-circuit area NPCA. The circuit area PCA and the non-circuit area NPCA may be provided extending in a first direction in the second display area DA2. In addition, a plurality of circuit areas PCA in the second display area DA2 may be alternately located with the non-circuit area NPCA in a second direction (y direction) crossing the first direction.

The circuit area PCA is an area in which the plurality of second pixel circuits PC2 are located, and the plurality of second pixel circuits PC2 may be continuously located in the first direction (x direction) in the circuit area PCA.

When looking at the first display area DA1 and the second display area DA2 as a whole, a first pixel circuit PC1 and a second pixel circuit PC2 may be continuously located in correspondence to a first row 1J. The first pixel circuit PC1 may be located in parallel to the non-circuit area NPCA of the second display area DA2 in correspondence to a second row 2J. Next, the first pixel circuit PC1 and the second pixel circuit PC2 may be continuously located in correspondence to a third row 3J. Then, the first pixel circuit PC1 may be located in parallel to the non-circuit area NPCA of the second display area DA2 in correspondence to a fourth row 4J. Such an arrangement may be continuously arranged to an end of the second display area DA2.

In one or more embodiments, the first pixel circuit PC1 and the second pixel circuit PC2 may identically provided. The first pixel circuit PC1 and the second pixel circuit PC2 may be differently provided.

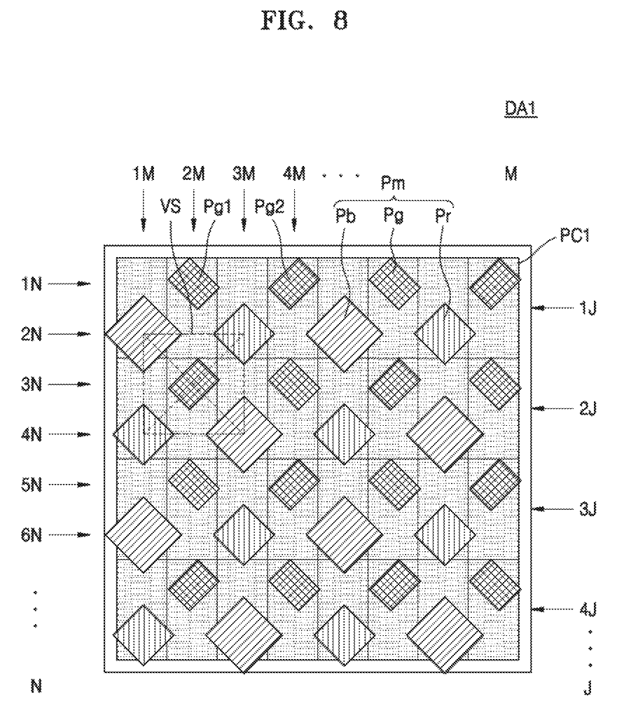

FIG. 8 is a schematic layout diagram of an arrangement structure of pixels that may be located in a first display area, according to one or more embodiments.

The plurality of main sub-pixels Pm may be located in the first display area DA1. In the disclosure, a sub-pixel is a minimum unit for realizing an image and refers to an emission area. When an organic light-emitting diode is used as a display element, the emission area may be defined by an opening of a pixel-defining layer.

In the first display area DA1, the first pixel circuit PC1 driving each of the main sub-pixels Pm may be located below the plurality of main sub-pixels Pm.

The main sub-pixels Pm located in the first display area DA1 may be located in a PENTILE^{TM} structure (PENTILE^{TM} being a registered trademark of Samsung Display Co., Ltd., Republic of Korea). A red sub-pixel Pr, a green sub-pixel Pg, and a blue sub-pixel Pb respectively implement red color, green color, and blue color.

In one or more embodiments, the red sub-pixel Pr, the green sub-pixel Pg, and the blue sub-pixel Pb may each be provided in a quadrangular shape.

In one or more embodiments, the red sub-pixel Pr and the blue sub-pixel Pb may each be provided in a rhombus shape. The green sub-pixel Pg may be provided in a rectangular shape, and may include a first green sub-pixel Pg1 whose long side is placed in a direction of -45 degrees with respect to an x direction, and a second green sub-pixel Pg2 whose long side is placed in a direction of about +45 degrees with respect to an x direction.

A plurality of first green sub-pixels Pg1 and a plurality of second green sub-pixels Pg2 may be alternately located in a first row 1N. A plurality of blue sub-pixels Pb and red sub-pixels Pr may be alternately located in a second row 2N adjacent to the first row 1N. The plurality of second green sub-pixels Pg2 and the plurality of first green sub-pixels Pg1 may be alternately located in a third row 3N adjacent to the second row 2N. The red sub-pixel Pr and the blue sub-pixel Pb may be alternately located in a fourth row 4N adjacent to the third row 3N, and such an arrangement may be repeatedly located up to an N-th row. At this time, the sizes of the blue sub-pixel Pb and the red sub-pixel Pr may be greater than that of the green sub-pixel Pg.

The plurality of green sub-pixels Pg located in the first row 1N and the plurality of red sub-pixels Pr and blue sub-pixels Pb located in the second row 2N are alternately located. Accordingly, the blue sub-pixel Pb and the red sub-pixel Pr may be alternately located in a first column 1M, the plurality of first green sub-pixels Pg1 and the plurality of second green sub-pixels Pg2 may be alternately located in a second column 2M adjacent to the first column 1M, the red sub-pixel Pr and the blue sub-pixel Pb may be alternately located in a third column 3M adjacent to the second column 2M, the plurality of second green sub-pixels Pg2 and the plurality of first green sub-pixels Pg1 may be alternately located in a fourth column 4M adjacent to the third column 3M, and such an arrangement of pixels may be repeated up to an M-th column.

When such an arrangement structure of the pixels is expressed differently, it may be expressed that the blue sub-pixels Pb are located at first and third vertices facing each other among vertices of a virtual quadrangle VS, in which a central point of the green sub-pixel Pg is a central point of the quadrangle, and red sub-pixels Pr are located at second and fourth vertices, which are the remaining vertices. At this time, the virtual quadrangle VS may be variously changed, such as a rectangle, a rhombus, a square, or the like.

Such an arrangement structure of the pixels may be referred to as a PENTILE^{TM} structure (PENTILE^{TM} being a registered trademark of Samsung Display Co., Ltd., Republic of Korea), and high resolution may be implemented with a small number of pixels by applying rendering driving that expresses colors by sharing adjacent pixels.

Although FIG. 8 illustrates that the plurality of main sub-pixels Pm are located in a PENTILE^{TM} structure (PENTILE^{TM} being a registered trademark of Samsung Display Co., Ltd., Republic of Korea), the disclosure is not limited thereto. For example, the plurality of main sub-pixels Pm may be located in various shapes, such as a stripe structure, a mosaic arrangement structure, a delta arrangement structure, or the like.

The first pixel circuits PC1 overlap the main sub-pixels Pm, and may be arranged in a matrix structure in the J rows and the M columns. One row of the first pixel circuits PC1 may correspond to two rows of main sub-pixels Pm. For example, the first row 1J of the first pixel circuits PC1 may correspond to the first row 1N and the second row 2N of the main sub-pixels Pm. The second row 2J of the first pixel circuits PC1 may correspond to the third row 3N and the fourth row 4N of the main sub-pixels Pm. One column of the first pixel circuits PC1 may correspond to one column of main sub-pixels Pm. The first column 1M of the first pixel circuits PC1 may correspond to the first column 1M of the main sub-pixels Pm.

The first display area DA1 does not consider light transmittance, and thus, with respect to sub-pixels of the same color, an area of the main sub-pixels Pm located in the first display area DA1 may be greater than an area of the auxiliary sub-pixels Pa located in the second display area DA2.

In one or more embodiments, an area of the red sub-pixel Pr located in the first display area DA1 may be about 348 μm² to about 616 μm², and an area of the green sub-pixel Pg may be about 322 μm² to about 514 μm², and an area of the blue sub-pixel Pb may be about 646 μm² to about 1300 μm².

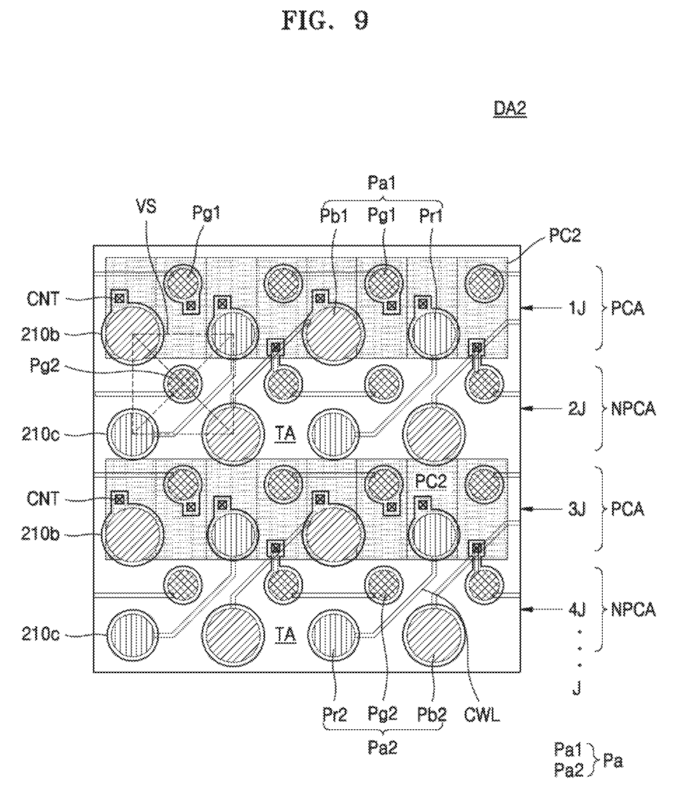

FIG. 9 is a schematic layout diagram of an arrangement structure of pixels in the second display area DA2 according to one or more embodiments.

Referring to FIG. 9, the plurality of auxiliary sub-pixels Pa may be located in the second display area DA2. The auxiliary sub-pixel Pa may mean an emission area of a second display element located in the second display area DA2.

In one or more embodiments, the same number of sub-pixels per unit area may be located in the second display area DA2 as the first display area DA1. That is, with respect to the same area, the number of auxiliary sub-pixels Pa located in the second display area DA2 may be the same as the number of main sub-pixels Pm located in the first display area DA1. Accordingly, the resolution of the first display area DA1 may be the same as the resolution of the second display area DA2.

In the second display area DA2, the second pixel circuits PC2 each concurrently or substantially simultaneously driving two auxiliary sub-pixels Pa may be located below the plurality of auxiliary sub-pixels Pa. That is, two display elements may be connected to each second pixel circuit PC2.

The second display area DA2 may include the circuit area PCA and the non-circuit area NPCA, and some of the auxiliary sub-pixels Pa may be located in the circuit area PCA, and the remaining thereof may be located in the non-circuit area NPCA.

The circuit area PCA may include the second pixel circuits PC2 continuously located in a first direction. The non-circuit area NPCA is an area in which pixel circuits are not located, and may be provided extending in the first direction. The circuit area PCA and the non-circuit area NPCA may be alternately located in a second direction.

An auxiliary sub-pixel Pa located in the circuit area PCA of the second display area DA2 may be referred to as a first auxiliary sub-pixel Pa1, and an auxiliary sub-pixel Pa located in the non-circuit area NPCA may be referred to as a second auxiliary sub-pixel Pa2. The first auxiliary sub-pixel Pa1 may include a first red sub-pixel Pr1, a first green sub-pixel Pg1, and a first blue sub-pixel Pb1. The second auxiliary sub-pixel Pa2 may include a second red sub-pixel Pr2, a second green sub-pixel Pg2, and a second blue sub-pixel Pb2.

The first red sub-pixel Pr1 may be connected to the second red sub-pixel Pr2 to be implemented by one second pixel circuit PC2. The first blue sub-pixel Pb1 may be connected to the second blue sub-pixel Pb2 to be implemented by the second pixel circuit PC2.

Two first green sub-pixels Pg1 may be connected to each other to be implemented by one second pixel circuit PC2. Two second green sub-pixels Pg2 may be connected to each other to be implemented by one second pixel circuit PC2. As such, sub-pixels that are implemented by one pixel circuit may be referred to as duplicate sub-pixels.

The auxiliary sub-pixels Pa may be connected by a connection line CWL. The connection line CWL may be a transparent connection line with high light transmittance. For example, the connection line CWL may include a transparent conductive oxide.

The auxiliary sub-pixels Pa located in the second display area DA2 may be located in a PENTILE^{TM} structure (PENTILE^{TM} being a registered trademark of Samsung Display Co., Ltd., Republic of Korea). The auxiliary sub-pixels Pa may be expressed in that first and second blue sub-pixels Pb1 and Pb2 may be located at first and third vertices facing each other among vertices of a virtual quadrangle VS, in which a central point of the green sub-pixel Pg2 is a central point of the quadrangle, and first and second red sub-pixels Pr1 and Pr2 may be located at second and fourth vertices, which are the remaining vertices. At this time, the virtual quadrangle VS may be variously changed, such as a rectangle, a rhombus, a square, or the like. The auxiliary sub-pixels Pa may have the same pixel arrangement structure as the main sub-pixels Pm.

In one or more embodiments, the auxiliary sub-pixel (e.g., an emission area of the second-1 display element) Pa may be provided in a different shape from that of the main sub-pixel (e.g., an emission aera of the first display element) Pm. The shape of the auxiliary sub-pixel Pa may be selected to have a shape that may improve the light transmittance of the second display area DA2.

In one or more embodiments, the auxiliary sub-pixel Pa may be provided in a circular shape. The red sub-pixel Pr, the green sub-pixel Pg, and the blue sub-pixel Pb, which are located in the second display area DA2, may each be provided in a circular shape. That is, an emission of a second display element located in the second display area DA2 may have the same shape as the auxiliary sub-pixel Pa, and may be provided in a circular shape.

In addition to the emission area, the second display element may include pixel electrodes 210b and 210c having generally circular shapes. The pixel electrode 210b of the second display element is connected to a pixel circuit through a contact hole CNT, and thus an area in the pixel electrode 210b, excluding an area where the contact hole CNT is located, may be provided in a circular shape. The pixel electrode 210c without a contact hole may be provided in an overall circular shape. To increase the emission area along the shapes of the pixel electrodes 210 and 210c, the emission area of the second display element may be provided in a circular shape. The lifespan of the second display element may be extended by such a design of the emission area.

As the pixel electrodes 210b and 210c of the second display element are provided in circular shapes, light passing through the second display area DA2 may be reduced in diffraction and reflection that may occur at an edge of the pixel electrodes 210b and 210c of the second display element, thereby increasing the light transmittance of the second display area DA2. In some embodiments, the shapes of the pixel electrodes 210b and 210c of the second display element may each be provided in a polygonal shape or in an elliptical shape with generally rounded corners.

The second pixel circuit PC2 is located in the circuit area PCA, but some light may also pass through the circuit area PCA. In one or more embodiments, because the shape of the pixel electrode 210b of the second display element implementing the first auxiliary sub-pixel Pa1 located in the circuit area PCA is provided in a circular shape, except for an area of the contact hole CNT, the light transmittance in the circuit area PCA may be increased.

In addition, in the non-circuit area NPCA, an area in which the auxiliary sub-pixel Pa is not located may be referred to as a transmission area TA. The transmission area TA may be an area where no light-blocking member is located from a substrate to a layer where a pixel electrode is located. The transmission area TA may be an area through which most light passes through in the second display area DA2.

A display panel according to one or more embodiments includes the non-circuit area NPCA including the transmission area TA in the second display area DA2 and has duplicate sub-pixels located therein, and thus may have high light transmittance while having the same resolution of the second display area DA2 as the first display area DA1.

In one or more embodiments, with respect to the same color, an area of the auxiliary sub-pixel Pa may be less than an area of the main sub-pixel Pm.

The area of the auxiliary sub-pixel Pa located in the second display area DA2 may be about 60% to about 80% of an area of the main sub-pixel Pm, based on sub-pixels having the same color.

In some embodiments, an area of the first and second red sub-pixels Pr1 and Pr2 located in the second display area DA2 may be about 310 μm² to about 442 μm², an area of the first and second green sub-pixels Pg1 and Pg2 may be about 192 μm² to about 422 μm², and an area of the first and second blue sub-pixels Pb1 and Pb2 may be about 278 μm² to about 808 μm².

As the area of the auxiliary sub-pixel Pa is smaller, the light transmittance of the second display area DA2 may be further improved. The area of the auxiliary sub-pixel Pa being smaller may mean that the area of the pixel electrode of the second display element implementing the auxiliary sub-pixel Pa may be smaller.

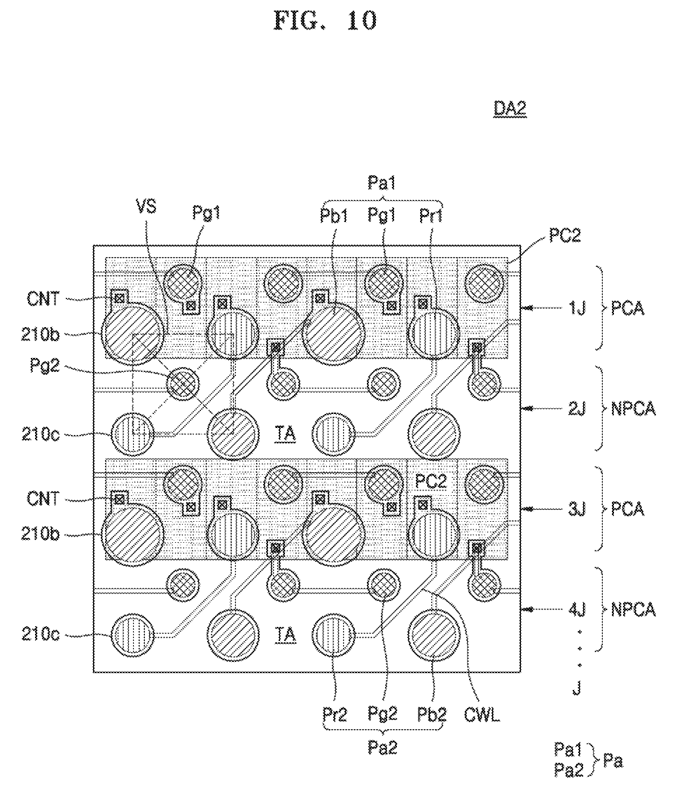

FIG. 10 is a schematic layout diagram of an arrangement structure of pixels in the second display area DA2 according to one or more embodiments. In FIG. 10, the same reference numerals in FIG. 9 denote the same members.

Referring to FIG. 10, the area of the second auxiliary sub-pixel Pa2 located in the non-circuit area NPCA may be less than the area of the first auxiliary sub-pixel Pa1, with respect to sub-pixels having the same color.

For example, an area of the second auxiliary sub-pixel Pa2 may be about 75% to about 80% of an area of the first auxiliary sub-pixel Pa1, with respect to sub-pixels having the same color.

Alternatively, the area of the first auxiliary sub-pixel Pa1 may be about 60% to about 80% of the area of the main sub-pixel Pm, with respect to sub-pixels having the same color, and the area of the second auxiliary sub-pixel Pa2 may be about 50% to about 60% of the area of the main sub-pixel Pm, with respect to the sub-pixels having the same color.

In some embodiments, the area of the first red sub-pixel Pr1 located in the circuit area PCA of the second display area DA2 may be about 310 μm² to about 442 μm², the area of the first green sub-pixel Pg1 may be about 192 μm² to about 422 μm², and the area of the first blue sub-pixel Pb1 may be about 278 μm² to about 808 μm².

The area of the second red sub-pixel Pr2 located in the non-circuit area NPCA of the second display area DA2 may be about 310 μm² to about 348 μm², the area of the second green sub-pixel Pg2 may be about 192 μm² to about 322 μm², and the second blue sub-pixel Pb2 may be about 278 μm² to about 646 μm².

In this case, a ratio that the transmission area TA occupies in the non-circuit area NPCA may be about 45% to about 52%.

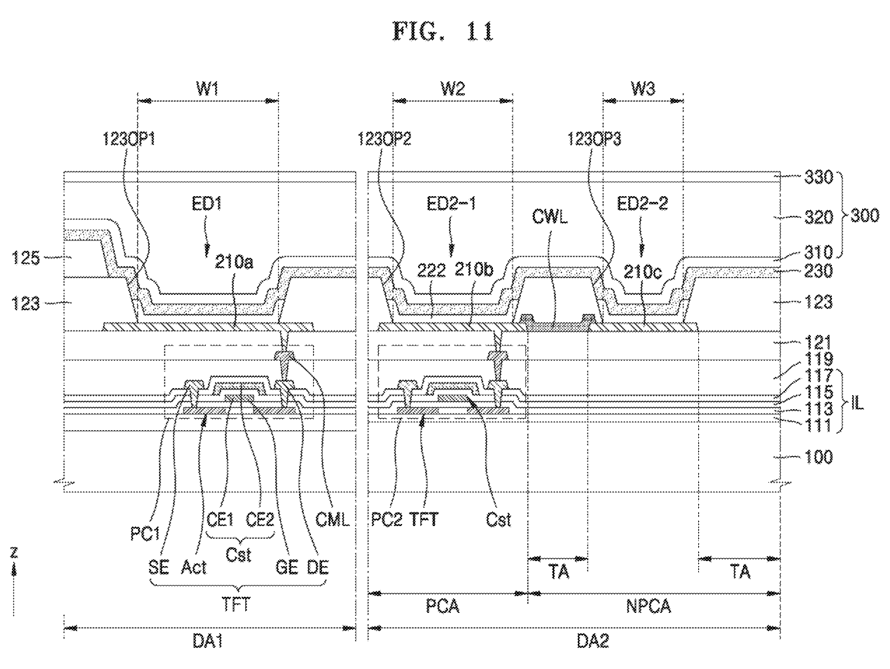

FIG. 11 is a schematic cross-sectional view of a display panel according to one or more embodiments. For example, FIG. 11 illustrates a portion of the first display area DA1 and a portion of the second display area DA2.

Referring to FIG. 11, the display panel according to one or more embodiments may include the substrate 100 including the first display area DA1 and the second display area DA2, a first light-emitting diode (e.g., first display element) ED1 located in the first display area DA1 and connected to the first pixel circuit PC1, and a second-1 light-emitting diode (e.g., second-1 display element) ED2-1 and a second-2 light-emitting diode (e.g., second-1 display element) ED2-2, which are located in the second display area DA2 and are connected to the second pixel circuit PC2.

The substrate 100 may include various materials, such as a glass material, a metal material, or a polymer resin. The polymer resin may include polyethersulfone, polyacrylate, polyetherimide, polyethylene naphthalate, PET, polyphenylene sulfide, polyarylate, PI, polycarbonate, and/or cellulose acetate propionate, or the like. The substrate 100 may also be provided in a structure in which a polymer resin and an inorganic insulating material are stacked.

The buffer layer 111 may be located on the substrate 100. The buffer layer 111 may reduce and block penetration of foreign materials, moisture, or external air from a lower portion of the substrate 100. The buffer layer 111 may include an inorganic insulating material, such as silicon oxide, silicon oxynitride, and silicon nitride, and may include a single-layered structure or a multi-layered structure, each including the material stated above.

The first light-emitting diode ED1 may be electrically connected to the first pixel circuit PC1. The second-1 light-emitting diode ED2-1 and the second-2 light-emitting diode ED2-2 may be electrically connected to the second pixel circuit PC2. The second-1 light-emitting diode ED2-1 may be located in the circuit area PCA to overlap the second pixel circuit PC2. The second-2 light-emitting diode ED2-2 may be located in the non-circuit area NPCA and may not overlap the second pixel circuit PC2.

Each of the first pixel circuit PC1 and the second pixel circuit PC2 may include a thin-film transistor TFT and a storage capacitor Cst. The thin-film transistor TFT may include a semiconductor layer Act, a gate electrode GE overlapping a channel area of the semiconductor layer Act, and a source electrode SE and a drain electrode DE, which are respectively connected to a source area and a drain area of the semiconductor layer Act. A gate-insulating layer 113 may be between the semiconductor layer Act and the gate electrode GE, and a first interlayer insulating layer 115 and a second interlayer insulating layer 117 may be located between the gate electrode GE and the source electrode SE, or between the gate electrode GE and the drain electrode DE.

The storage capacitor Cst may overlap the thin-film transistor TFT. The storage capacitor Cst may include a lower electrode CE1 and an upper electrode CE2, which overlap each other. In some embodiments, the gate electrode GE of the thin-film transistor TFT may include the lower electrode CE1 of the storage capacitor Cst. The first interlayer insulating layer 115 may be located between the lower electrode CE1 and the upper electrode CE2.

The semiconductor layer Act may include polysilicon. In some embodiments, the semiconductor layer Act may include amorphous silicon. In some embodiments, the semiconductor layer Act may include an oxide semiconductor of at least one material selected from a group consisting of indium (In), gallium (Ga), tin (Sn), zirconium (Zr), vanadium (V), hafnium (Hf), cadmium (Cd), germanium (Ge), chromium (Cr), titanium (Ti), and/or zinc (Zn). The semiconductor layer Act may include the channel area, the source area, and the drain area, wherein the source area and the drain area are doped with impurities.

The gate-insulating layer 113 may include an inorganic insulating material, such as silicon oxide, silicon oxynitride, and silicon nitride, and may include a single-layered structure or a multi-layered structure, each including the material stated above.

The gate electrode GE or the lower electrode CE1 may include a low-resistance conductive material, such as molybdenum (Mo), aluminum (Al), copper (Cu), and/or titanium (Ti), and may include a single-layered structure or a multi-layered structure, each including the material stated above.

The first interlayer insulating layer 115 may include an inorganic insulating material, such as silicon oxide, silicon oxynitride, and silicon nitride, and may include a single-layered structure or a multi-layered structure, each including the material stated above.

The upper electrode CE2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu, and may include a single-layered structure or a multi-layered structure, each including the material stated above.

The second interlayer insulating layer 117 may include an inorganic insulating material, such as silicon oxide, silicon oxynitride, and silicon nitride, and may include a single-layered structure or a multi-layered structure, each including the material stated above.

The source electrode SE and/or the drain electrode DE may include Al, Pt, Pd, Ag, Mg, Au, Ni, Nd, Ir, Cr, Ni, Ca, Mo, Ti, W, and/or Cu, and may include a single-layered structure or a multi-layered structure, each including the material stated above. For example, the source electrode SE and/or the drain electrode DE may include a three-layered structure of Ti layer/Al layer/Ti layer.

A first organic insulating layer 119 may be positioned on the thin-film transistor TFT, and the thin-film transistor TFT may be electrically connected to a first pixel electrode 210a of a corresponding organic light-emitting diode through a connection electrode layer CML located on the first organic insulating layer 119. The connection electrode layer CML may be connected to the thin-film transistor TFT through a contact hole in the first organic insulating layer 119, and the first pixel electrode 210a may be connected to the connection electrode layer CML through a contact hole in a second organic insulating layer 121.

The first organic insulating layer 119 and/or the second organic insulating layer 121 may include an organic insulating layer, such as benzocyclobutene (BCB), PI, or hexamethyldisiloxane (HMDSO). In some embodiments, the connection electrode layer CML and the second organic insulating layer 121 may be omitted, and in this case, the pixel electrode 210 may be directly connected to the thin-film transistor TFT through a contact hole in the first organic insulating layer 119.

The first light-emitting diode ED1, the second-1 light-emitting diode ED2-1, and the second-2 light-emitting diode ED2-2 may be organic light-emitting diodes, and may include stacked structures of first to third pixel electrodes 210a, 210b, and 210c, an emission layer 222, and an opposite electrode 230, respectively. In one or more embodiments, the stacked structure described above may include a first functional layer between the first to third pixel electrodes 210a, 210b, and 210cand the emission layer 222 and/or a second functional layer between the emission layer 222 and the opposite electrode 230.

The first to third pixel electrodes 210a, 210b, and 210c may be positioned on the second organic insulating layer 121. The first to third pixel electrodes 210a, 210b, and 210c may each include a reflective film, the reflective film including Ag, Mg, Al, Pt, Pd, Au, Ni, Nd, Ir, Cr, or a compound thereof. The first to third pixel electrodes 210a, 210b, and 210c may each include a reflective film including the material described above, and a transparent conductive film located above or/and below the reflective film. The transparent conductive film may include indium tin oxide (ITO), indium zinc oxide (IZO), zinc oxide (ZnO), indium oxide (In₂O₃), indium gallium oxide (IGO), and/or aluminum zinc oxide (AZO). In one or more embodiments, the pixel electrode 210 may have a three-layered structure of ITO layer/Ag layer/ ITO layer.

A pixel-defining layer 123 may cover edges of the first to third pixel electrodes 210a, 210b, and 210c, and may include, or define, openings overlapping the first to third pixel electrodes 210a, 210b, and 210c. In this regard, FIG. 11 illustrates an opening (hereinafter, referred to as a first opening 123OP1) overlapping the first pixel electrode 210a of the first light-emitting diode ED1, an opening (hereinafter, referred to as a second opening 123OP2) overlapping the second pixel electrode 210b of the second-1 light-emitting diode ED2-1, and an opening (hereinafter, referred to as a third opening 123OP3) overlapping the third pixel electrode 210c of the second-2 light-emitting diode ED2-2.

The first opening 123OP1 of the pixel-defining layer 123 may define an emission area of the first light-emitting diode ED1. The second opening 123OP2 of the pixel-defining layer 123 may define an emission area of the second-1 light-emitting diode ED2-1, and the third opening 123OP3 may define an emission area of the second-2 light-emitting diode ED2-2.

For example, a first width W1 of the first opening 123OP1 of the pixel-defining layer 123 may correspond to a width of the emission area of the first light-emitting diode ED1. A second width W2 of the second opening 123OP2 of the pixel-defining layer 123 may correspond to a width of the emission area of the second-1 light-emitting diode ED2-1, and a third width W3 of the third opening 123OP3 may correspond to a width of the emission area of the second-2 light-emitting diode ED2-2.

In one or more embodiments, a size or area of the emission area of the first light-emitting diode ED1 may be greater than a size or area of the emission area of the second-1 light-emitting diode ED2-1, which, in turn, may be greater than a size or area of the emission area of the second-2 light-emitting diode ED2-2. To express the above case, in the drawing, the first width W1 is shown to be greater than the second width W2, which is shown to be greater than the third width W3 (W1 > W2 > W3). At this time, the first light-emitting diode (e.g., the first display element) ED1, the second-1 light-emitting diode (e.g., the second-1 display element) ED2-1, and the second-2 light-emitting diode (e.g., the second-2 display element) ED2-2 may emit light of the same color.

In addition, in one or more embodiments, a size or area of the first pixel electrode 210a may be greater than a size or area of the second pixel electrode 210b, which, in turn, may be greater than a size or area of the third pixel electrode 210c.

Through such a configuration, the resolution of the second display area DA2 is configured to be the same as the first display area DA1, and the size of the transmission area TA of the second display area DA2 and the overall transmittance of the second display area DA2 may be improved.

A spacer 125 may be located on the pixel-defining layer 123. The spacer 125 may protrude from an upper surface of the pixel-defining layer 123. The spacer 125 may be configured to reduce or prevent damage during a mask process of forming the emission layer 222 or the like.

The spacer 125 may be formed of an organic insulating material, such as PI, polyamide, acrylic resin, BCB, HMDSO, and phenol resin in a spin coating method or the like. The spacer 125 may be formed of the same material in the same process as the pixel-defining layer 123. In this case, the thicknesses of the spacer 125 and the pixel-defining layer 123 may be made different by using a mask including full tone and half-tone.

The emission layer 222 may be positioned to correspond to each of the first opening 123OP1 and the second opening 123OP2 of the pixel-defining layer 123, and may overlap the first pixel electrode 210a and the second pixel electrode 210b. The emission layer 222 may include a polymer organic material or a low-molecular-weight organic material, which emits light of a certain color. In one or more embodiments, a first functional layer and a second functional layer may be formed below and above the emission layer 222.

The first functional layer may include a hole transport layer (HTL) and/or a hole injection layer (HIL). The second functional layer may include an electron transport layer (ETL) and/or an electron injection layer (EIL). The first functional layer and/or the second functional layer may be entirely formed on the substrate 100, unlike the emission layer 222. In other words, the first functional layer and/or the second functional layer may cover the first display area DA1 and the second display area DA2.

The opposite electrode 230 may be located on the emission layer 222. The opposite electrode 230 may include a conductive material having a low work function. For example, the opposite electrode 230 may include a (semi)transparent layer including Ag, Mg, Al, Pt, Pd, Au, Ni, Nd, Ir, Cr, Li, Ca, alloys thereof, or the like. Alternatively, the opposite electrode 230 may further include a layer, such as ITO, IZO, ZnO, or In₂O₃,above the (semi)transparent layer including the materials stated above. The opposite electrode 230 may be integrally formed to correspond light-emitting diodes located in the first display area DA1 and the second display area DA2.

The second-2 light-emitting diode ED2-2 may be connected to the second pixel circuit PC2 through a connection line CWL. In detail, the third pixel electrode 210c of the second-2 light-emitting diode ED2-2 may be connected to the second pixel electrode 210b of the second-1 light-emitting diode ED2-1 by the connection line CWL. The connection line CWL may be formed on the second organic insulating layer 121, which is the same layer as the second pixel electrode 210b and the third pixel electrode 210c, and may cover edges of the second pixel electrode 210b and the third pixel electrode 210c.

The connection line CWL may include a transparent line. For example, the connection line CWL may include a transparent conducting oxide (TCO). That is, the connection line CWL may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO).

The connection line CWL includes a transparent line, and an area in which the connection line CWL is located may be referred to as the transmission area TA. In the second display area DA2, an area in the non-circuit area NPCA, in which the third pixel electrode 210c is not located, may be referred to as the transmission area TA.

A thin-film encapsulation layer 300 may cover the first light-emitting diode ED1, the second-1 light-emitting diode ED2-1, and the second-2 light-emitting diode ED2-2. In one or more embodiments, the thin-film encapsulation layer 300 may include a first inorganic encapsulation layer 310, a second inorganic encapsulation layer 330, and an organic encapsulation layer 320 between the first inorganic encapsulation layer 310 and the second inorganic encapsulation layer 330.

The first and second inorganic encapsulation layers 310 and 330 may respectively include one or more inorganic insulating materials. The inorganic insulating materials may include aluminum oxide, titanium oxide, tantalum oxide, hafnium oxide, silicon oxide, silicon nitride, and/or silicon oxynitride.

The organic encapsulation layer 320 may include a polymer-based material. The polymer-based material may include an acrylic resin, an epoxy resin, PI, polyethylene, or the like. For example, the organic encapsulation layer 320 may include an acrylic resin, for example, polymethyl methacrylate, polyacrylic acid, or the like. The organic encapsulation layer 320 may be formed by curing a monomer or coating a polymer.

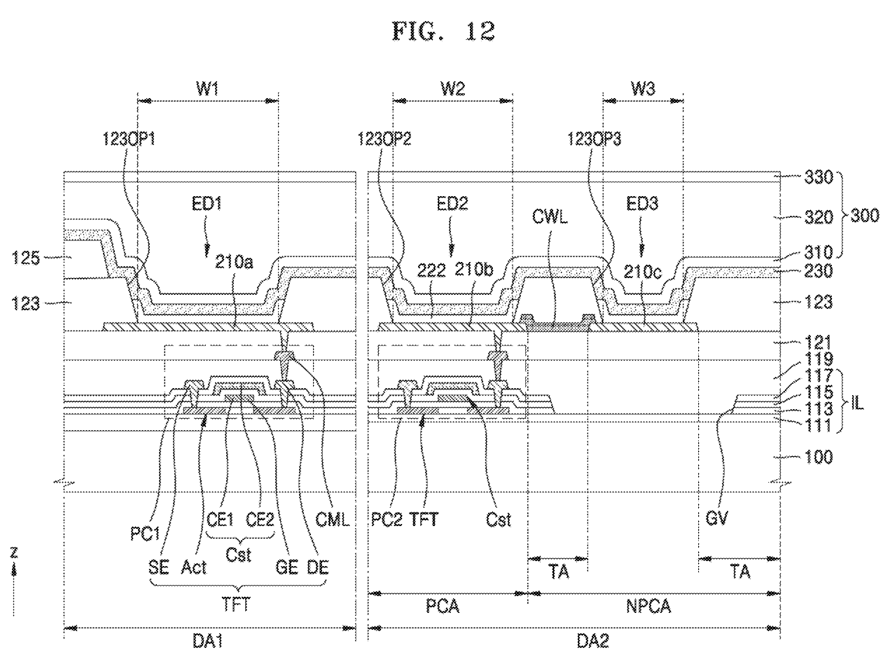

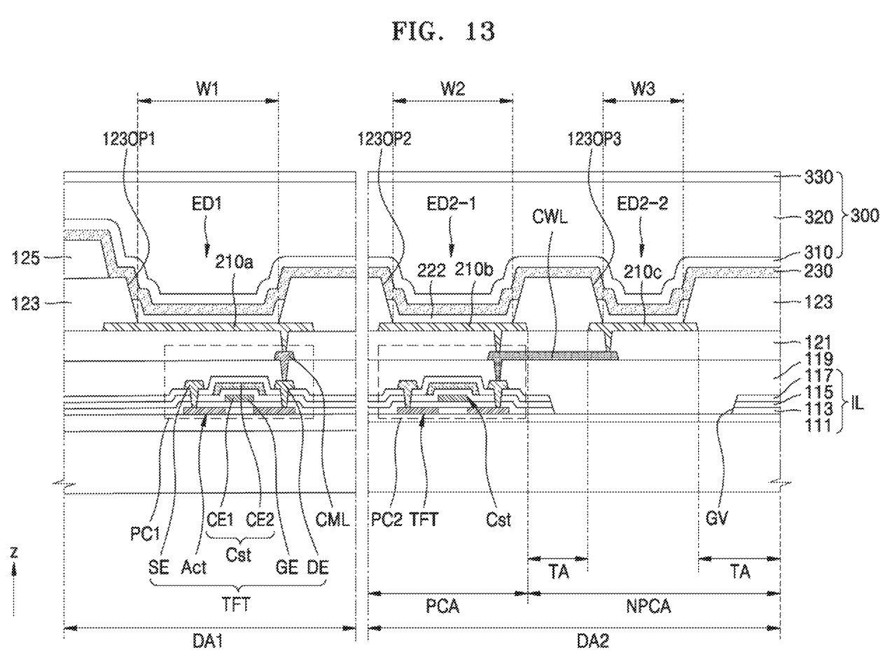

FIGS. 12 and 13 are schematic cross-sectional views illustrating display panels according to embodiments. In FIGS. 12 and 13, the same reference numerals as those in FIG. 11 refer to the same members.

Referring to FIGS. 12 and 13, the display panel according to one or more embodiments may include the substrate 100 including the first display area DA1 and the second display area DA2, the first light-emitting diode ED1 located in the first display area DA1 and connected to the first pixel circuit PC1, and the second-1 light-emitting diode ED2-1 and the second-2 light-emitting diode ED2-2, which are located in the second display area DA2 and connected to the second pixel circuit PC2. The second-1 light-emitting diode ED2-1 may overlap the second pixel circuit PC2, and the second-2 light-emitting diode ED2-2 may not overlap the second pixel circuit PC2.

The size or area of the emission area of the first light-emitting diode ED1 may be greater than the size or area of the emission area of the second-1 light-emitting diode ED2-1, and the size and area of the emission area of the second-1 light-emitting diode ED2-1 may be greater than the size or area of the emission area of the second-2 light-emitting diode ED2-2. To express the above case, in the drawing, the first width W1 is shown to be greater than the second width W2, and the second width W2 is shown to be greater than the third width W3 (W1 > W2 > W3). At this time, the first light-emitting diode ED1, the second-1 light-emitting diode ED2-1, and the second-2 light-emitting diode ED2-2 may emit light of the same color.

In addition, the size or area of the first pixel electrode 210a may be greater than the size or area of the second pixel electrode 210b, which may be greater than the size or area of the third pixel electrode 210c.

In one or more embodiments, when the buffer layer 111, the gate-insulating layer 113, the first interlayer insulating layer 115, and the second interlayer insulating layer 117 are collectively referred to as an inorganic insulating layer IL, the inorganic insulating layer IL may have a groove GV or opening corresponding to the second display area DA2.

The groove GV may be provided by removing a portion of the inorganic insulating layer IL. For example, the buffer layer 111 may be continuously located across the second display area DA2, and the gate-insulating layer 113, the first interlayer insulating layer 115, the second interlayer insulating layer 117 may have, or define, openings corresponding to the second display area DA2. These openings may be formed individually through separate processes or concurrently or substantially simultaneously through the same process. When these openings are formed in separate processes, an inner surface of the groove GV may not be smooth and may have a step-difference like a staircase shape.

FIG. 12 illustrates that openings are formed in the gate-insulating layer 113, the first interlayer insulating layer 115, and the second interlayer insulating layer 117 to correspond to the groove GV of the inorganic insulating layer IL, but the disclosure is not limited thereto. Openings may not be formed in, or may be omitted from, a portion of the gate-insulating layer 113, the first interlayer insulating layer 115, and the second interlayer insulating layer 117.

In addition, the inorganic insulating layer IL may have an opening corresponding to the second display area DA2. That is, an opening may also be formed in the buffer layer 111 of the inorganic insulating layer IL to expose an upper surface of the substrate 100.

The first organic insulating layer 119 may fill the groove GV or opening of the inorganic insulating layer IL. The first organic insulating layer 119 may have higher light transmittance than that of the inorganic insulating layer IL. Accordingly, the light transmittance of the second display area DA2 may be improved.

In FIG. 12, the connection line CWL connecting the second-1 light-emitting diode ED2-1 to the second-2 light-emitting diode ED2-2 is located on the same layer as the second and third pixel electrodes 210b and 210c, but the disclosure is not limited thereto.

As shown in FIG. 13, the connection line CWL may be located on a different layer from the second and third pixel electrodes 210b and 210c. For example, the connection line CWL may be located on the first organic insulating layer 119, which is below the second organic insulating layer 121. In this case, the second-1 light-emitting diode ED2-1 and the second-2 light-emitting diode ED2-2 may be connected to the connection line CWL through a contact hole.

The display panel according to the embodiments described above may be applied to various electronic devices. An electronic device according to one or more embodiments may include the display panel described above, and may further include modules or devices having different additional functions, in addition to the display panel.

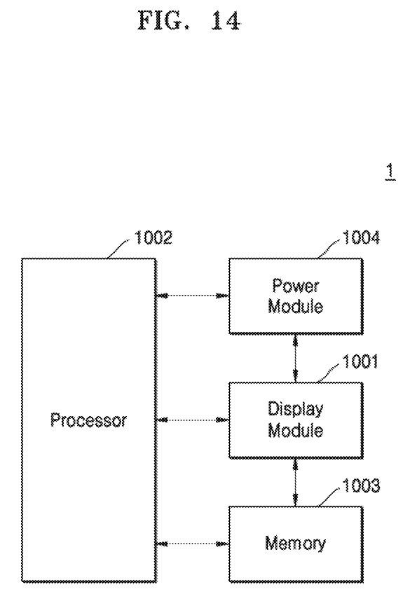

FIG. 14 is a block diagram of an electronic device according to one or more embodiments. Referring to FIG. 14, the electronic device 1 according to one or more embodiments may include a display module 1001, a processor 1002, a memory 1003, and a power module 1004.

The processor 1002 may include at least one of a central processing unit (CPU), an application processor (AP), a graphics processing unit (GPU), a communication processor (CP), an image signal processor (ISP), or a controller.

Data information suitable for an operation of the processor 1002 or the display module 1001 may be stored in the memory 1003. When the processor 1002 executes an application stored in the memory 1003, an image data signal and/or input control signal may be transmitted to the display module 1001, and the display module 1001 may process the received signal and output image information through a display screen.

The power module 1004 may include a power supply module, such as a power adapter or a battery device, and a power conversion module that generates power suitable for an operation of the electronic device 1 by converting power supplied by the power supply module.

At least one of the configurations of the electronic device 1 described above may be included in the display panel according to the embodiments described above. In addition, some of the individual modules functionally included within a module may be included in the display panel, and the others may also be provided separately from the display panel. For example, the display panel may include the display module 1001, and the processor 1002, the memory 1003, and the power module 1004 may be provided in a form of other devices within the electronic device 1 instead of the display panel.

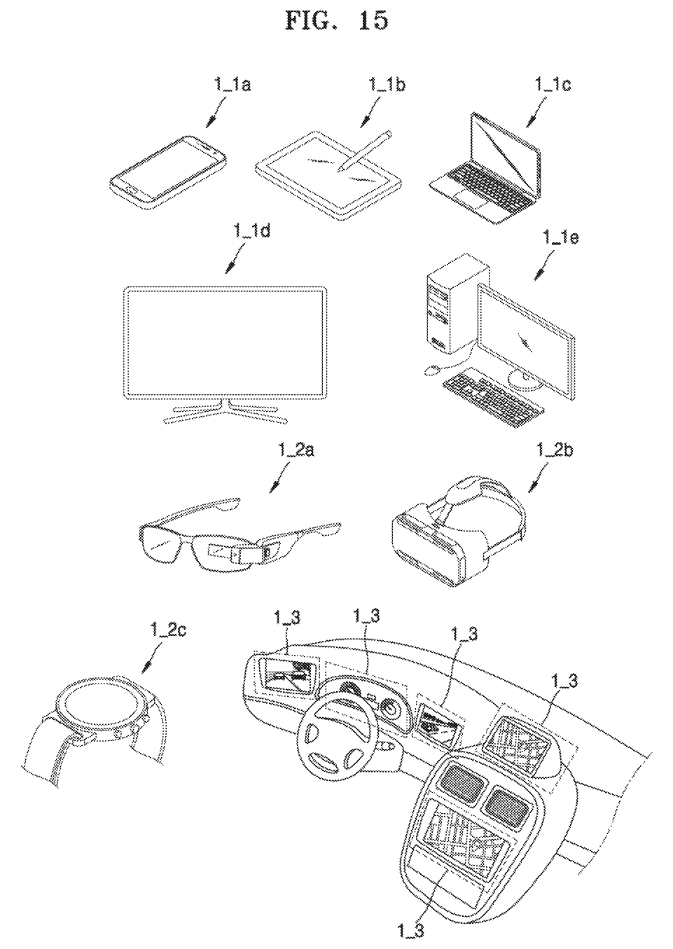

FIG. 15 shows schematic diagrams of electronic devices according to various embodiments.

Referring to FIG. 15, electronic devices according to embodiments may not only include electronic devices for image display, such as a smart phone 1_1a, a tablet personal computer (PC) 1_1b, a laptop 1_1c, a television (TV) 1_1d, a desk monitor 1_1e, but may also include wearable electronic devices including display modules, such as smart glasses 1_2a, a head-mounted display 1_2b, a smart watch 1_2c, or the like, and electronic devices 1_3 for a vehicle including display modules, such as a dashboard of a vehicle, a center fascia, a center information display (CID) located on a dashboard, a room mirror display, or the like.

A display panel according to one or more embodiments may provide differences in the shapes and/or sizes of emission areas of a first display area and a second display area, thereby configuring the resolution of the first display area and the resolution of the second display area to be the same while increasing the light transmittance of the second display area.

The scope of the disclosure is not limited by the above aspects. It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display panel comprising:
a substrate comprising a first display area, and a second display area comprising a circuit area and a non-circuit area;
a first pixel circuit in the first display area;
a first display element connected to the first pixel circuit;
a second pixel circuit in the circuit area of the second display area;
a second-1 display element in the circuit area, connected to the second pixel circuit, configured to emit light of a same color as the first display element, and having an emission area having a shape that is different from a shape of an emission area of the first display element; and
a second-2 display element in the non-circuit area and connected to the second pixel circuit.

2. The display panel of claim 1, wherein the circuit area and the non-circuit area extend in a first direction in the second display area, and
wherein the circuit area and the non-circuit area are provided in plurality and alternately arranged in a second direction crossing the first direction.

3. The display panel of claim 1, wherein a number of sub-pixels in the first display area per unit area is substantially equal to a number of sub-pixels in the second display area per unit area.

4. The display panel of claim 1, wherein a planar shape of the emission area of the first display element is quadrangular, and
wherein a planar shape of the emission area of the second-1 display element and a planar shape of an emission area of the second-2 display element are circular.

5. The display panel of claim 1, wherein a size of the emission area of the first display element is greater than a size of the emission area of the second-1 display element.

6. The display panel of claim 1, wherein the second-1 display element and the second-2 display element are configured to emit light of a same color, and
wherein a size of the emission area of the second-1 display element is greater than a size of an emission area of the second-2 display element.

7. The display panel of claim 1, wherein the second-1 display element and the second-2 display element are configured to emit light of a same color, and
wherein a size of a pixel electrode of the second-1 display element is greater than a size of a pixel electrode of the second-2 display element.

8. The display panel of claim 1, wherein a pixel electrode of the second-1 display element and a pixel electrode of the second-2 display element are connected to each other by a connection line.

9. The display panel of claim 8, wherein the connection line comprises a transparent conductive oxide.

10. The display panel of claim 8, wherein the connection line is at a same layer as the pixel electrode of the second-1 display element.

11. The display panel of claim 8, wherein the connection line is at a different layer from the pixel electrode of the second-1 display element.

12. The display panel of claim 1, further comprising an inorganic insulating layer above the substrate and defining an opening or groove corresponding to the non-circuit area.

13. The display panel of claim 1, wherein the first pixel circuit comprises a driving transistor comprising an oxide semiconductor material, and a switching transistor comprising a silicon semiconductor material.

14. An electronic device comprising:
a processor; and
a display panel configured to be driven by the processor, and comprising:
a substrate comprising a first display area and a second display area comprising a circuit area and a non-circuit area;
a first pixel circuit in the first display area;
a first display element connected to the first pixel circuit;
a second pixel circuit in the circuit area;
a second-1 display element in the circuit area, connected to the second pixel circuit, configured to emit light of a same color as the first display element, and having an emission area having a shape that is different from a shape of an emission area of the first display element; and
a second-2 display element in the non-circuit area and connected to the second pixel circuit.

15. The electronic device of claim 14, wherein a number of sub-pixels in the first display area per unit area is substantially equal to a number of sub-pixels in the second display area per unit area.

16. The electronic device of claim 14, wherein a planar shape of the emission area of the first display element is quadrangular, and
wherein a planar shape of the emission area of the second-1 display element and a planar shape of an emission area of the second-2 display element are circular.

17. The electronic device of claim 14, wherein the first display element, the second-1 display element, and the second-2 display element comprise light-emitting diodes configured to emit light of a same color,
wherein a size of the emission area of the first display element is greater than a size of the emission area of the second-1 display element, and
wherein the size of the emission area of the second-1 display element is greater than a size of an emission area of the second-2 display element.

18. The electronic device of claim 14, wherein a pixel electrode of the second-1 display element and a pixel electrode of the second-2 display element are connected to each other by a connection line.

19. The electronic device of claim 18, wherein the connection line comprises a transparent conductive oxide.

20. The electronic device of claim 14, further comprising a component below the display panel, and overlapping the second display area.
